(19) United States
(12) Patent Application Publication
(10) Pub. No.: US 2021/0265323 A1
(43) Pub. Date: Aug. 26, 2021

(54) DISPLAY DEVICE

(71) Applicant: OSRAM OLED GmbH, Regensburg (DE)

(72) Inventor: Hubert HALBRITTER, Dietfurt (DE)

(21) Appl. No.: 17/253,048

(22) PCT Filed: Aug. 7, 2019
(86) PCT No.: PCT/EP2019/071265

§ 371 Date: Dec. 16, 2020

(30) Foreign Application Priority Data
Aug. 10, 2018 (DE) 10 2018 119 548.6

(51) Int. Cl. H01L 25/075; H01L 25/04; H01L 25/16

(52) U.S. Cl. CPC H01L 25/0753; G06K 9/0004; H01L 25/167; H01L 25/048

(57) ABSTRACT

A display device includes a plurality of pixels arranged in a regular main grid. Several optoelectronic additional chips are used to generate radiation. The pixels are formed by individually controllable light-emitting regions. The additional chips are arranged in a secondary grid. The secondary grid is offset from the main grid so that the additional chips are positioned away from the grid points of the main grid.

A display device is specified.

One task to be solved is to specify a display device where additional functions are efficiently integrated within a display surface.

This task is solved, inter alia, by a display device with the features of claim 1. Preferred further developments are subject-matter of the other claims.

In particular a display device is specified, which comprises many pixels, between which distributed light sources for, for example, infrared are arranged. Over the additional light sources a radiation source, for example for a face recognition, is space-savingly realizable.

According to at least one embodiment, the display device comprises a plurality of pixels. The pixels are arranged in a regular main grid. Preferably red, blue and green light is emitted from the pixels with an adjustable intensity. This means that the pixels may be so-called RGB pixels. Via the pixels it is thus possible to display colored images and/or movies with the display device.

According to at least one embodiment, the display device comprises several optoelectronic additional chips. The additional chips may all be identical in construction or several types of different additional chips are used. The additional chips are configured for radiation generation, in particular for the generation of near infrared radiation.

According to at least one embodiment, the pixels are formed by individually controllable light-emitting regions. This means that the pixels are in this case not realized by a backlight together with a liquid crystal mask, but by individual, self-light-emitting regions. A downstream filter mask such as a liquid crystal mask is therefore not required. The light-emitting regions and thus the pixels are controlled by an active matrix circuit or a passive matrix circuit, for example.

According to at least one embodiment, the light-emitting regions are based on an organic and/or an inorganic semiconductor material. Inorganic semiconductor materials are preferred because inorganic semiconductor materials can generate light of higher intensity per unit area than organic semiconductor materials. Thus, pixels based on an inorganic semiconductor material may be smaller and larger gaps between adjacent pixels are possible.

According to at least one embodiment, the additional chips are arranged in at least one secondary grid. The secondary grid may be regular or irregular. It is possible to combine several regular secondary grids and to arrange the additional chips distributed on grid points of the several secondary grids.

According to at least one embodiment, the at least one secondary grid is offset from the main grid. This means that some or all grid points of the secondary grid preferably do not coincide with grid points of the main grid. This allows to position the additional chips away from the grid points of the main grid. In other words, the additional chips do not represent a substitution of pixels, but preferably form independent components in addition to the pixels. In particular, an arrangement, especially a regular arrangement, of the pixels is not or not significantly affected or disturbed by the additional chips.

In at least one embodiment the display device comprises a plurality of pixels arranged in a regular main grid. Several optoelectronic additional chips are used to generate radiation. The pixels are formed by individually controllable light-emitting regions. The light-emitting regions are based on an organic and/or an inorganic semiconductor material. The additional chips are arranged in a secondary grid. The secondary grid is offset from the main grid so that the additional chips are positioned away from the grid points of the main grid.

Displays in mobile devices such as smartphones usually require a cutout for an infrared illumination source and/or a camera. This is increasingly undesirable, as such a cutout limits the effective image size and reduces the overall visual impression.

In particular, the use of light-emitting diode chips, also known as LEDs, as the light source for the individual pixels results in a comparatively large free space between the individual pixels and/or the LEDs for the pixels, depending on the grid dimension of the pixels. This especially applies when so-called μLEDs are used. Such μLEDs typically comprise edge dimensions in the range around 10 μm.

The space between the pixels is preferably filled with lasers such as μVCSELs or IREDs. These serve as a distributed light source and no longer need to be designed as a discrete component next to the display. In addition, each individual additional chip, especially in the form of the μVCSELs and/or the μIREDs, can be controlled and/or modulated very quickly, as only a few μA are required for powering each. In addition, the same control chip, in particular a μIC, which controls the RGB pixels, can also be used to control the additional chips.

If the individual additional chips are equipped with an optic, the radiation of each additional chip can be imaged accordingly. This allows both homogeneous illumination scenarios and structured imaging, also known as structured light, to be realized.

By arranging the additional chips between the pixels, no additional space for an additional light source is necessary. Due to the fact that in particular the μVCSELs are distributed, there are no problems regarding eye safety. Since the μVCSELs, for example, require only a small amount of μA of operating current, this also results in fast modulation, unlike large, discrete chips that require a few amperes of current and are therefore inductively limited in terms of their switching times. Furthermore, customized optics like meter optics, diffractive optics or refractive optics for the additional chips are possible, which allow an adapted illumination scenario from the surface.

According to at least one embodiment, the display device comprises at least 0.3 million pixels or 1 million pixels or 3.5 million pixels. Thus, the display device may be used to display high resolution images or movies.

According to at least one embodiment, there is a maximum of 100000 or 10000 or 1000 of the additional chips. This means that a comparatively small number of the additional chips is sufficient to achieve the additional function such as infrared illumination.

According to at least one embodiment there are at least a factor of 100 or 500 or 1000 more pixels than additional chips. Compared to the pixels, there are therefore only very few of the additional chips. Accordingly, the secondary grid in which the additional chips are arranged can comprise a much larger grid dimension than the main grid in which the pixels are arranged.

According to at least one embodiment, the grid dimension of the main grid is at least 30 μm or 50 μm. Alternatively or additionally, the grid dimension of the main grid is at most 200 μm or 150 μm or 100 μm. The preferred size of the pixels is at most 90% or 80% or 50% of the grid dimension of the main grid. This means that the pixels can be relatively small compared to the grid dimension of the main grid.

According to at least one embodiment, the additional chips comprise an average edge length of at most 50 μm or 20 μm or 10 μm when viewed from above. Alternatively or additionally, the average edge length of the additional chips is at least 1 μm or 2 μm or 5 μm or 10 μm.

According to at least one embodiment, the additional chips are arranged at a distance from the pixels. This means that the additional chips and the light-emitting regions of the pixels and/or semiconductor chips of the pixels do not touch each other. A distance between the additional chips and the pixels and/or their light-emitting regions is, for example, at least 5% or 10% or 20% of the grid dimension of the main grid.

According to at least one embodiment, the pixels each comprise a light-emitting region for red, green and blue light. The light-emitting regions of each pixel are preferably electrically controllable independently of each other. This means that the pixels may be configured as RGB pixels.

According to at least one embodiment, the pixels are each formed by one or more light-emitting diode chips. For example, there is an LED chip for generating red light, an LED chip for generating green light and an LED chip for generating blue light. The respective light may be generated directly in a semiconductor layer sequence of the corresponding LED chips or by wavelength conversion using at least one phosphor. If at least one phosphor is used, the light-emitting diode chips of the pixels emit preferably near-ultraviolet radiation or blue light and can thus all be of identical construction.

The semiconductor layer sequence is preferably based on a III-V compound semiconductor material. The semiconductor material is for example a nitride compound semiconductor material like AlₙIn₁₋ₙ₋ₘGaₘN or a phosphide compound semiconductor material like AlₙIn₁₋ₙ₋ₘGaₘP or also around an arsenide compound semiconductor material such as AlₙIn₁₋ₙ₋ₘGaₘAs or such as AlₙGaₘIn₁₋ₙ₋ₘAsₖP₁₋ₖ, where 0≤n≤1, 0≤m≤1 and n+m≤1 and 0≤k<1 respectively. Preferably for at least one layer or for all layers of the semiconductor layer sequence 0<n≤0.8, 0.4≤m<1 and n+m≤0.95 as well as 0<k≤0.5. The semiconductor layer sequence may comprise dopants as well as additional components. However, for the sake of simplicity, only the essential constituents of the crystal lattice of the semiconductor layer sequence, i.e. Al, As, Ga, In, N or P, are given, even if these may be partially replaced and/or supplemented by small amounts of other substances. Preferably, the semiconductor layer sequence is based on AlInGaN.

According to at least one embodiment, the pixels are each formed by light-emitting organic regions. For each emission color there is preferably one separately controllable light-emitting region per pixel. This means that the display device may be a so-called OLED display.

According to at least one embodiment, some or all of the additional chips are formed by lasers. In particular, the lasers or at least part of the lasers are lasers with a vertical resonator. Such lasers are also called VCSELs, where VCSEL stands for Vertical Cavity Surface Emitting Laser. Due to the preferably small dimensions of the additional chips in the μm range with edge lengths of 20 μm or 10 μm in particular, such lasers may also be called μVCSELs.

According to at least one embodiment, some or all of the additional chips are formed by LED chips and/or IRED chips. IRED stands for InfraRed Emitting Diode. Again, the additional chips in this case preferably comprise small dimensions so that the additional chips are formed by μLEDs or μIREDs.

According to at least one embodiment, some of the additional chips are formed by photodetector chips and/or by touch sensor chips or there are corresponding detector chips in addition to the additional chips. Thus, a sensor such as a touch sensor or a camera or a photodetector can also be distributed over the display device in the region between the pixels.

According to at least one embodiment the display device comprises several control chips. The control chips are preferably configured to drive the additional chips and/or the additional detector chips and/or the pixels. It is possible that the control chips drive at least a part of the pixels as well as the additional chips.

According to at least one embodiment, the control chips are arranged in the same secondary grid or in one of the secondary grids as the additional chips and/or the detector chips. Alternatively, the control chips are located in intermediate regions between the main grid and the secondary grid. This means that the control chips are then arranged neither in the main grid nor in the at least one secondary grid.

According to at least one embodiment, at least a part of the additional chips are configured to emit near-infrared radiation. A wavelength of maximum intensity of these additional chips is preferably at least 800 nm and/or at most 1000 nm, especially around 850 nm or around 940 nm.

According to at least one embodiment, the additional chips together are adapted for an optical radiation power of at least 1 W or 2 W or 3 W and/or of at most 5 W. Individual additional chips are preferably intended for a radiation power of at least 0.3 mW or 1 mW or 3 mW and/or of at most 50 mW or 15 mW. The additional chips preferably do not emit the radiation continuously, but in a pulsed manner for only short time ranges. Thus, the power consumption of the additional chips is preferably significantly lower on a time average than the power consumption of the pixels.

According to at least one embodiment there are several different types of additional chips. The different types of additional chips are preferably configured to emit radiation of different wavelengths of maximum intensity. For example, one or more types of additional chips are present, which emit in the near ultraviolet or blue spectral range. There may also be additional chips that emit in the visible spectral range at wavelengths not covered by the pixels themselves. Furthermore, the additional chips may emit in different regions of the near-infrared spectral range.

Additional chips emitting at different wavelengths may be used, for example, for spectroscopic applications such as determination of the freshness of food or simplification of color matching of cosmetics. If additional chips with different emission wavelengths are present, the different emission wavelengths are preferably emitted chronologically one after the other to achieve wavelength resolution. Alternatively, the additional chips with different emission wavelengths may be operated simultaneously.

According to at least one embodiment, the additional chips are unevenly distributed over the display device. Thus it is possible that the display device is free of the additional chips in certain regions. Thus, regions with a certain density of the additional chips may be present, whereby this density does not vary in the respective regions, and the display device is completely free of the additional chips in certain regions. Alternatively, the additional chips are distributed with a continuous gradient so that the display device comprises a high density of additional chips in some regions and a low density of additional chips in others.

According to at least one embodiment, the display device comprises one or more optics. The at least one optic is intended for the additional chips.

According to at least one embodiment, the at least one optic is arranged at a distance from the at least one associated additional chip. For example, a distance between the optics and the additional chip is at least 50 μm or 100 μm. This means that the distance between the optics and the additional chip can be significantly larger than the lateral dimensions of the additional chip.

According to at least one embodiment, the optic is located directly on and/or on top of the associated additional chip. This allows a low overall height of the display device to be achieved.

According to at least one embodiment, the respective optics for the additional chips are integrated in a cover plate of the display device. The cover plate, which is for example formed of glass or plastic, preferably commonly covers the pixels and the additional chips. Thus, a separate optical component for the additional chips is not necessary.

According to at least one embodiment, at least some of the additional chips are configured to generate radiation pulses with a duration of at most 20 ns or 10 ns or 2 ns. This is possible in particular by using VCSELs. Additional chips that emit radiation pulses of a short duration can be used, for example, for distance measurement or time-of-flight measurement.

According to at least one embodiment, some or all of the additional chips are configured for biometric measurement. For example, the additional chips serve as a light source for face recognition and/or fingerprint identification.

According to at least one embodiment, the display device is a display of a smartphone. Alternatively, the display device is a display for a portable computer such as a tablet or notebook. Furthermore, the display device may be a display of a wrist device such as a watch or a bodily functions meter. The display device may also be used in other mobile devices.

In the following, a display device described here is explained in more detail with reference to the drawing using exemplary embodiments. Identical reference signs indicate identical elements in the individual figures. However, no scale references are shown, but individual elements may be shown in exaggerated size for better understanding.

In the figures:

FIG. 1 shows a schematic top view of a smartphone display with a modification of a display device,

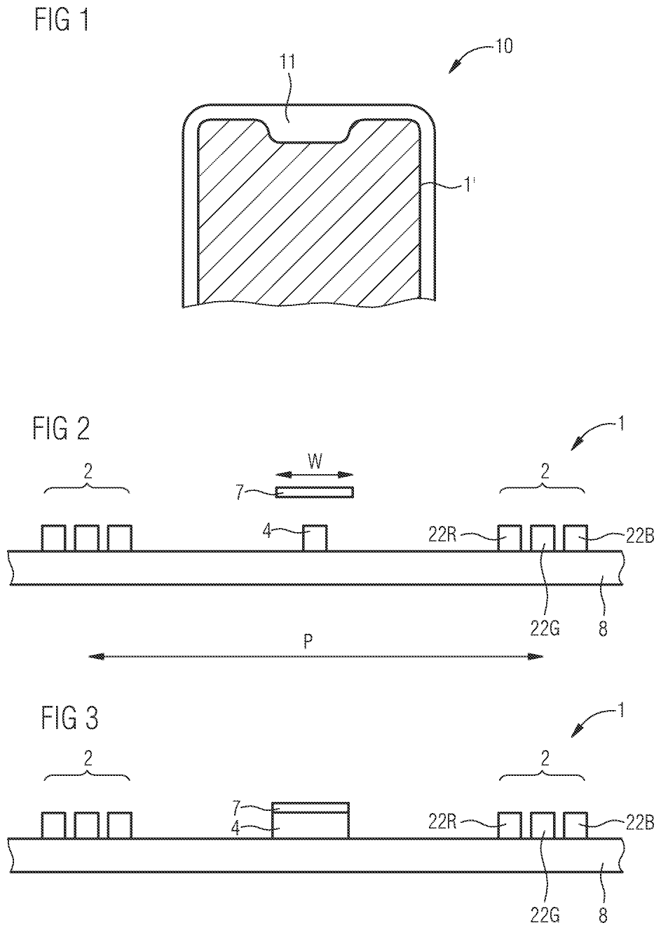

FIGS. 2 to 7 schematic sectional views of exemplary embodiments of display devices described here, and

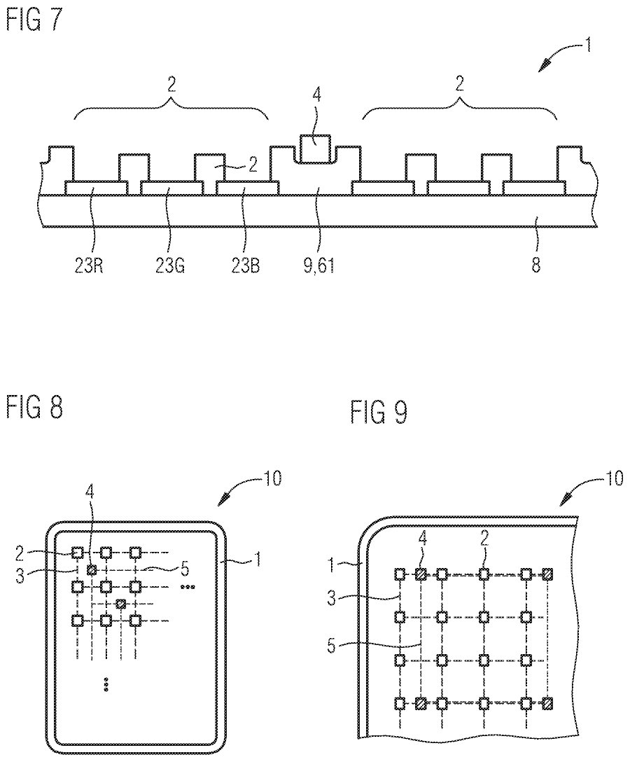

FIGS. 8 to 11 schematic top views on smartphones with exemplary embodiments of the display devices described here.

FIG. 1 shows a smartphone 10 with a modification 1′ of a display device. At a top end, the modification 1′ comprises a relatively large cutout 11. In the cutout 11 there is, for example, a point projector for structured light, an infrared flash for illumination for face recognition and/or an infrared camera. By the cutout 11 a usable surface for the modification 1′ of the display device is reduced. With the display devices 1 described below, the size of cutout 11 may be significantly reduced or it is possible that cutout 11 is completely omitted.

FIG. 2 illustrates an exemplary embodiment of the display device 1. On a carrier 8 such as a printed circuit board, a plurality of pixels 2 are arranged. The pixels 2 are for example each formed by a red emitting-light emitting diode chip 22R, a green emitting-light emitting diode chip 22G and a blue emitting-light emitting diode chip 22B. The light-emitting diode chips 22R, 22G, 22B may be controlled electrically independently of each other. The light-emitting diode chips 22R, 22G, 22B are preferably so-called μLEDs, which comprise only small lateral dimensions.

A grid dimension T of an arrangement of pixels 2, for example, is approximately 85 μm. Since the light-emitting diode chips 22R, 22G, 22B are comparatively small, there is a comparatively large free region on the carrier 8 between adjacent pixels 2. This free region contains at least one additional chip 4. The additional chip 4 is preferably a source of near infrared radiation. For example, the additional chip 4 is formed by a μIRED or a μVCSEL. This means that laser radiation may optionally be generated by the additional chip 4.

The additional chip 4 is preferably located in a common plane with the light-emitting diode chips 22R, 22G, 22B. In particular, the additional chip 4 is located centrally between adjacent pixels 2. Deviating from the illustration in FIG. 2, the additional chip 4 may also be positioned eccentrically between the pixels 2.

Optionally, an optic 7 may be assigned to the additional chip 4. The optic 7 is, for example, a refractive optic such as a lens or a meta-optic made of an optical metamaterial. Furthermore, the optic 7 may be formed by a diffractive optical element, also known as DOE.

Lateral dimensions of the optic 7 are preferably larger than lateral dimensions of the additional chip 4. For example, a width W of the optic 7 is at least 10 μm and/or at most 50 μm. The same applies to all other exemplary embodiments.

If the additional chip 4 is a VCSEL, the additional chip 4 may comprise a single aperture and/or a single laser unit or it may comprise several apertures and/or several laser units. For example, a single aperture and/or laser unit comprises lateral dimensions in the range around 2 μm. Thus, the additional chip 4 may comprise a 3×3 array or a 5×5 array of VCSEL units.

The exemplary embodiment of FIG. 3 illustrates that the optic 7 is mounted directly or very close to the additional chip 4. In lateral direction, i.e. parallel to the carrier 8, the optic 7 may be flush or approximately flush with the additional chip 4. For example, there is only a bonding agent such as an adhesive between the optic 7 and the additional chip 4, not shown. The optic 7 may be monolithic or hybrid integrated.

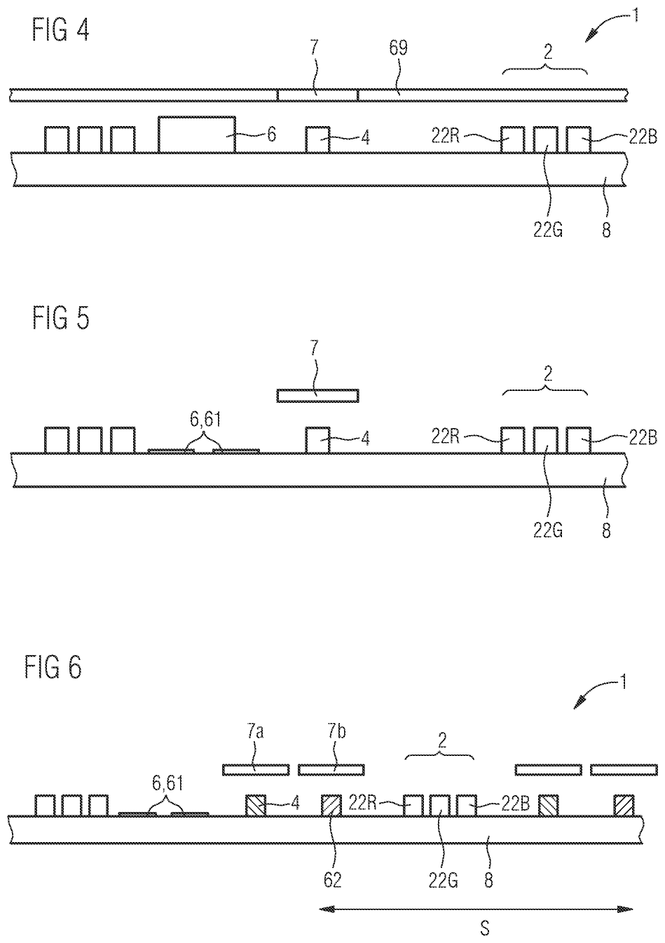

In the exemplary embodiment in FIG. 4, there are also control chips 6 arranged between the adjacent pixels 2. For example, each of the additional chips 4 is assigned one of the control chips 6. Several additional chips 4 may also be assigned to one control chip 6 each. The control chip 6, for example, is an IC.

The at least one control chip 6 is, for example, located on a further grid. This means that the pixels 2 and the additional chips 4 are located on a main grid 3 and on a secondary grid 5, whereby the at least one control chip 6 is not located on these grids. It is possible that there is a separate grid for the control chips 6, which may, for example, comprise its own grid dimension, which may differ from a grid dimension for the pixels 2 and the additional chips 4, or may correspond to a grid dimension for the additional chips 4.

Furthermore, FIG. 4 illustrates that the optic 7 for the shown additional chip 4 may be integrated in a cover plate 69. This means that optic 7 for the additional chip 4 does not need to be a separate optical element; instead, the optic 7 may be integrated into cover plate 69 above the pixels 2.

The exemplary embodiment in FIG. 5 illustrates that several thin-film transistors 61 may be present as an alternative or in addition to the control chips 6. The at least one thin-film transistor 61 may be used to interconnect and/or wire the pixels 2 and/or the additional chips 4.

With regard to an arrangement of the thin-film transistors 61, the statements regarding the control chips 6 in FIG. 4 apply accordingly.

In the exemplary embodiment of FIG. 6, there are several photodetector chips 62 in addition to the additional chips 4. The photodetector chips 62 can be arranged in a further, preferably regular grid. A sensor distance S between adjacent photodetector chips 62 is, for example, around 100 μm. This allows a fingerprint scanner to be realized using the photodetector chips 62.

The sensor distance S, which can correspond to a grid dimension of the arrangement of the photodetector chips 62, is preferably equal to the grid dimension T of the pixels 2 or a grid dimension of the secondary grid for the additional chips 4. The photodetector chips 62 can be distributed over the entire display device 1 or only be accommodated in certain regions of the display device 1.

It is possible that the photodetector chips 62 are each assigned their own optic 7b. Thus, different types of optics 7a may be present for the additional chips 4 and optics 7b for the photodetector chips 62. The optics 7a, 7b may be integrated, in accordance with FIG. 4, in a cover plate that is not shown in FIG. 6.

Instead of photodetector chips 62, differently designed detector chips may also be used, for example for touch sensitivity. Corresponding detector chips are based on a capacitively working principle, for example.

In the exemplary embodiment of FIG. 7, the pixels 2 each comprise light-emitting organic regions 23R, 23G, 23B for the independent generation of red, green and blue light. A wiring 9 is provided to control the regions 23R, 23G, 23B. In addition, the regions 23R, 23G, 23B are controlled by thin-film transistors 61, for example, which can be mounted between adjacent pixels 2.

Compared to the exemplary embodiments of FIGS. 2 to 6, the light-emitting organic regions 23R, 23G, 23B occupy a comparatively large portion of an upper side of the carrier 8. This means that there is only a comparatively small intermediate region between adjacent pixels 2. The additional chips 4 are located in this intermediate region. For this purpose, the additional chips 4 may be placed above the thin-film transistors 61 and above the wiring 9. This allows a space-saving arrangement of the additional chips 4.

FIG. 8 shows a top view of a Smartphone 10, which includes an exemplary embodiment of the display device 1. The display device 1, for example, is designed as described in connection with FIGS. 2 to 7.

The plurality of pixels 2 is arranged in a main grid 3. The additional chips 4 are arranged in a secondary grid 5. Both grids 3, 5 may be formed by regular square or rectangular grids with different grid dimensions.

A density of the additional chips 4 is much lower than a density of the pixels 2, i.e. there are significantly more pixels 2 than additional chips 4.

The additional chips 4, for example, are located approximately on diagonals between the pixels 2, which means that the additional chips 4 can lie off the grid lines of the main grid 3.

FIG. 9 illustrates that the additional chips 4 lie on the connecting lines of the main grid 3. As seen in the left-right direction of FIG. 9, the additional chips 4 are thus located between adjacent pixels 2.

The display device 1, for example, comprises about 4 million pixels 2, especially for a resolution of 1200×1900 pixels. However, there are preferably less than 1000 of the additional chips 4, which are realized in particular by μVCSELs. Eye safety can be achieved by distributing the additional chips 4 over a comparatively large area, for example over the entire smartphone 10, since the intensity of the radiation is locally only relatively low.

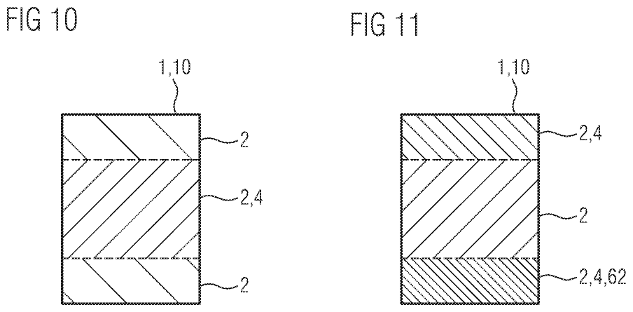

FIG. 10 illustrates that the additional chips 4 are not distributed over the entire display device 1, but are concentrated in a central region, for example. A lower region and optionally also an upper region of the display device 1 may be free of the additional chips 4, so that, for example, only the pixels 2 are located in the upper and lower regions.

FIG. 11 illustrates that an upper regions of the display device 1 contains the pixels 2 and the additional chips 4. Such an arrangement may be used to achieve efficient illumination for face recognition, for example.

Alternatively or additionally, the additional chips 4, the pixels 2 and the photodetector chips 62 are located in a lower region of the display device 1. In this way, fingerprint identification may be efficiently realized in the lower region, for example.

In the exemplary embodiments of FIGS. 8 to 11, there may be one front side camera present, which is not drawn. Compared to the modification in FIG. 1, however, such a camera takes up only a comparatively small space on the front side, since no separate light source has to be placed next to the display device.

If the photodetector chips 62 are distributed over the entire front side, as shown in FIG. 11, it is also possible that a dedicated front side camera can be omitted. An image for face recognition, for example, can then be calculated from the individual signals of the photodetector chips 62 distributed over the display device 1.

Unless otherwise indicated, the components shown in the figures preferably follow each other directly in the order given. Layers not touching each other in the figures are preferably spaced apart. If lines are drawn parallel to each other, the corresponding surfaces are preferably aligned parallel to each other. Likewise, unless otherwise indicated, the relative positions of the drawn components to each other are correctly shown in the figures.

The invention is not restricted to the exemplary embodiments by the description on the basis of said exemplary embodiments. Rather, the invention encompasses any new feature and also any combination of features, which in particular comprises any combination of features in the patent claims and any combination of features in the exemplary embodiments, even if this feature or this combination itself is not explicitly specified in the patent claims or exemplary embodiments.

This patent application claims the priority of German patent application 10 2018 119 548.6, the disclosure content of which is hereby incorporated by reference.

### REFERENCES

1 display device

1′ modification of a display device

2 pixel

22 light-emitting diode chip

23 light-emitting organic region

3 main grid

4 additional chip

5 secondary grid

6 control chip

61 thin-film transistor

62 photodetector chip

69 cover plate

7 optic

8 carrier

9 wiring

10 smartphone

11 cutout

P grid dimension of the pixels

S sensor distance

W width of the optic

1. A display device comprising:
a plurality of pixels arranged in a regular main grid, and
several optoelectronic additional chips for radiation generation,
wherein
the pixels are formed by individually controllable light-emitting regions,
the light-emitting regions are based on an organic and/or on an inorganic semiconductor material,
the additional chips are arranged in a secondary grid, and
the secondary grid is offset from the main grid so that the additional chips are positioned away from grid points of the main grid,
there are at least by a factor of 500 more pixels than additional chips, and
at least a part of the additional chips is adapted to emit near-infrared radiation with a maximum intensity wavelength between 800 nm and 1 μm inclusive, and these additional chips together are adapted for an optical radiation power of at least 1 W.

2. The display device according to claim 1, which comprises at least 0.3 million pixels,
with a maximum of 10,000 of the additional chips.

3. The display device according to claim 1, wherein there are at least by a factor of 1000 more pixels than additional chips.

4. The display device according to claim 1,
wherein a grid dimension of the main grid is between 30 μm and 150 μm inclusive,
wherein the additional chips comprise an average edge length of at most 20 μm when viewed from above, and
wherein the additional chips are arranged at a distance from the pixels, and
wherein the pixels are each configured to emit red, green and blue light independently of each other.

5. The display device according to claim 1,
wherein the pixels are each formed by at least one light-emitting diode chip.

6. The display device according to claim 1,
wherein the pixels are each formed by light-emitting organic regions, so that the display device is an OLED display.

7. The display device according to claim 1,
wherein at least a part of the additional chips is formed by lasers having a vertical resonator.

8. The display device according to claim 1,
wherein at least a part of the additional chips is formed by IRED chips.

9. The display device according to claim 1,
further comprising a plurality of detector chips formed by photodetector chips and/or by touch sensor chips.

10. The display device according to claim 1,
further comprising several control chips,
wherein the control chips are arranged either in the secondary grid or in intermediate regions between the main grid and the secondary grid.

11. The display device according to o claim 1,
wherein there are several different types of additional chips, which are configured to emit radiation of different wavelengths of maximum intensity.

12. The display device according to o claim 1,
wherein the additional chips are distributed unevenly so that the display device is free of the additional chips in certain regions.

13. The display device according to on claim 1,
further comprising at least one optic for the additional chips,
wherein the optic is arranged at a distance from the at least one associated additional chip.

14. The display device according to claim 13,
wherein the optic is integrated in a cover plate of the display device,
wherein the cover plate commonly covers the pixels and the additional chips so that a separate optical component for the additional chips is not required.

15. The display device according to claim 1,
wherein at least some of the additional chips are configured to generate radiation pulses with a duration of at most 10 ns, so that a distance measurement is possible by means of these additional chips.

16. The display device according to claim 1,
wherein at least some of the additional chips are configured for biometric measurement, in particular for facial recognition and/or for fingerprint identification.

17. The display device according to claim 1,
which is a display of a smartphone.

18. A display device comprising:
a plurality of pixels arranged in a regular main grid,
several optoelectronic additional chips for radiation generation, and
several control chips,
wherein
the pixels are formed by individually controllable light-emitting regions,
the light-emitting regions are based on an organic and/or on an inorganic semiconductor material,
the additional chips are arranged in a secondary grid, and
the secondary grid is offset from the main grid so that the additional chips are positioned away from grid points of the main grid,
there are at least a factor of 500 more pixels than additional chips,
at least a part of the additional chips is adapted to emit near-infrared radiation with a maximum intensity wavelength between 800 nm and 1 μm inclusive, and these additional chips together are adapted for an optical radiation power of at least 1 W,
the control chips are arranged either in the secondary grid or in intermediate regions between the main grid and the secondary grid, and
the control chips are arranged in a common plane with the pixels and the additional chips.
